(19) United States
(12) Patent Application Publication
(10) Pub. No.: US 2024/0059967 A1
(43) Pub. Date: Feb. 22, 2024

(54) ETCHING COMPOSITION AND METHOD OF MANUFACTURING INTEGRATED CIRCUITS USING THE SAME

(71) Applicant: SAMSUNG ELECTRONICS CO., LTD., Suwon-si (KR)

(72) Inventors: Daihyun KIM, Suwon-si (KR); Taesoo KWON, Seoul (KR); Yeonsoek YOO, Seoul (KR); Mihyun PARK, Suwon-si (KR); Sangwon BAE, Suwon-si (KR); Hyosan LEE, Suwon-si (KR); Wook JANG, Seoul (KR)

(73) Assignee: Oci Company Ltd., Seoul (KR)

(21) Appl. No.: 18/227,454

(22) Filed: Jul. 28, 2023

(30) Foreign Application Priority Data
Aug. 18, 2022 (KR) 10-2022-0103559

(51) Int. Cl. C09K 13/06; H01L 29/66

(52) U.S. Cl. CPC C09K 13/06; H01L 29/66795

(57) ABSTRACT

An etching composition for etching a titanium aluminum nitride layer and a method of manufacturing an integrated circuit, the etching composition includes about 15 wt % to about 30 wt % of an oxidizing agent; about 1 wt % to about 10 wt % of a pH adjusting agent, the pH adjusting agent including an inorganic acid or an organic acid; about 0.001 wt % to about 1 wt % of an etching booster; and a solvent, all wt % being based on a total weight of the etching composition.

### CROSS-REFERENCE TO RELATED APPLICATION

This application is based on and claims priority under 35 U.S.C. § 119 to Korean Patent Application No. 10-2022-0103559, filed on Aug. 18, 2022, in the Korean Intellectual Property Office, the disclosure of which is incorporated by reference herein in its entirety.

### BACKGROUND

### 1. Field

Embodiments relate to an etching composition and a method of manufacturing integrated circuits by using the etching composition.

### 2. Description of the Related Art

Due to the development of electronics technology, the demand for high integration of an integrated circuit has increased, and downscaling is in progress.

### SUMMARY

The embodiments may be realized by providing an etching composition for etching a titanium aluminum nitride layer, the etching composition including about 15 wt % to about 30 wt % of an oxidizing agent; about 1 wt % to about 10 wt % of a pH adjusting agent, the pH adjusting agent including an inorganic acid or an organic acid; about 0.001 wt % to about 1 wt % of an etching booster; and a solvent, all wt % being based on a total weight of the etching composition.

The embodiments may be realized by providing a method of manufacturing an integrated circuit, the method including forming a semiconductor pattern on a substrate; forming a gate insulating layer on the semiconductor pattern; forming a titanium aluminum nitride layer on the gate insulating layer; and performing an etching process using an etching composition on the titanium aluminum nitride layer to remove the titanium aluminum nitride layer, wherein the etching composition includes about 15 wt % to about 30 wt % of an oxidizing agent, about 1 wt % to about 10 wt % of a pH adjusting agent, the pH adjusting agent including an inorganic acid or an organic acid, about 0.001 wt % to about 1 wt % of an etching booster, and a solvent, all wt % being based on a total weight of the etching composition.

The embodiments may be realized by providing a method of manufacturing an integrated circuit, the method including forming a first semiconductor pattern structure on a first region of a substrate such that the first semiconductor pattern structure includes a plurality of first semiconductor patterns separated from each other; forming a second semiconductor pattern structure on a second region of the substrate such that the second semiconductor pattern structure includes a plurality of second semiconductor patterns separated from each other; forming a gate insulating layer on the first semiconductor pattern structure and the second semiconductor pattern structure; forming a metal-containing layer on the gate insulating layer such that the metal-containing layer includes a titanium aluminum nitride; forming a mask pattern that covers a first portion of the metal-containing layer on the first region and does not cover a second portion of the metal-containing layer on the second region; and performing an etching process using an etching composition on the second portion of the metal-containing layer to remove the second portion of the metal-containing layer, wherein the etching composition includes about 15 wt % to about 30 wt % of an oxidizing agent, about 1 wt % to about 10 wt % of a pH adjusting agent, the pH adjusting agent including an inorganic acid or an organic acid, about 0.001 wt % to about 1 wt % of an etching booster, and a solvent, all wt % being based on a total weight of the etching composition.

### BRIEF DESCRIPTION OF THE DRAWINGS

Features will be apparent to those of skill in the art by describing in detail exemplary embodiments with reference to the attached drawings in which:

FIGS. 1A, 2A, 5A, and 12A are plan views of stages in manufacturing processes of an integrated circuit according to example embodiments, FIGS. 1B, 2B, 3, 4, 5B, 6A, 7A, 8A, 9A, 10A, 11A, and 12B are cross-sectional views taken along lines A1-A1′ and A2-A2′ of FIG. 1A, and FIGS. 1C, 2C, 6B, 7B, 8B, 9B, 10B, 11B, and 12C are cross-sectional views taken along line B1-B1′ of FIG. 1A;

FIG. 13 is a graph illustrating an etching rate using various etching compositions according to an experimental example; and

FIG. 14 is a graph illustrating an etching rate using various etching compositions according to an experimental example.

### DETAILED DESCRIPTION OF THE EMBODIMENTS

An etching composition according to example embodiments may include an etching composition for etching a metal-containing layer and may include an etching composition for etching a metal nitride, e.g., a titanium nitride or a titanium aluminum nitride. In an implementation, the etching composition may include an etching composition for etching a titanium aluminum nitride layer, e.g., may include an etching composition with a relatively high etching rate for a titanium aluminum nitride layer including aluminum of a relatively high concentration.

The etching composition according to example embodiments may include, e.g., about 15 wt % to about 30 wt % of an oxidizing agent, about 1 wt % to about 10 wt % of a pH adjusting agent (including an inorganic or organic acid), about 0.001 wt % to about 1 wt % of an etching booster (including, e.g., a nitric acid, a phosphoric acid, a hydrochloric acid chelator, or a compound containing the same), and a solvent (e.g., in a balance amount). All wt % are based on a total weight of the composition.

In an implementation, the oxidizing agent may include, e.g., hydrogen peroxide, nitric acid, or ammonium sulfate. In an implementation, the oxidizing agent may include hydrogen peroxide. The oxidizing agent may oxidize a metal-containing layer, e.g., a titanium aluminum nitride layer, and may help adjust an etching rate of the etching composition. As used herein, the term “or” is not an exclusive term, e.g., “A or B” would include A, B, or A and B.

In an implementation, the oxidizing agent may be included in an amount of about 15 wt % to about 30 wt % in the etching composition. If the content of the oxidizing agent were to be less than 15 wt %, an etching rate of the metal-containing layer could decrease and an etching time could increase, and accordingly, a throughput of an etching process could be reduced. If the content of the oxidizing agent were to be greater than 30 wt %, etching selectivity of an etching target layer with respect to a lower layer quality could be reduced. If an etching rate of a target layer were to increase and an etching rate of a lower layer were to also increase, it could be difficult to precisely control a selective etching process of the target layer with respect to the lower layer. If the content of the oxidizing agent were to be greater than 30 wt %, it could be difficult to increase stability in a treatment process of a chemical material including an etching composition.

In an implementation, the oxidizing agent may be included in an amount of, e.g., about 15 wt % to about 20 wt %, about 15 wt % to about 25 wt %, about 15 wt % to about 30 wt %, about 20 wt % to about 25 wt %, about 20 wt % to about 30 wt %, or about 25 wt % to about 30 wt %.

The pH adjusting agent may include an inorganic acid or an organic acid, and may be included in the composition in an amount of about 1 wt % to about 10 wt %. In an implementation, the pH adjusting agent may include, e.g., phosphoric acid, nitric acid, sulfuric acid, hydrochloric acid, acetic acid, methanesulfonic acid, ethanesulfonic acid, benzenesulfonic acid, sulfanilic acid, sulfamic acid, malonic acid, glycolic acid, formic acid, citric acid, oxalic acid, propionic acid, acrylic acid, lactic acid, or butyric acid.

In an implementation, the pH adjusting agent may have a content suitable to adjust a pH of an etching composition. In an implementation, the etching composition may have a pH that is greater than 0 and less than or equal to 3, and in this range, an etching rate of the etching composition with respect to the metal-containing layer may be optimized. In an implementation, the pH adjusting agent may be included in an amount of about 1 wt % to about 10 wt % in the etching composition. If the content of the pH adjusting agent were to be less than 1 wt %, the etching rate of the metal-containing layer could be reduced and an etching time could increase, and accordingly, a throughput of an etching process could be reduced. If the content of the pH adjusting agent were to be greater than 10 wt %, etching selectivity of an etching target layer with respect to a lower layer could be reduced, and an etching rate of a material (e.g., the lower layer) other than the etching target layer could also increase, and thus, it could be difficult to precisely control a selective etching process of the etching target layer.

The etching composition according to example embodiments may include nitric acid, phosphoric acid, a hydrochloric acid chelator, or a compound including the same. In an implementation, the nitric acid, the phosphoric acid, the hydrochloric acid chelator, or the compound including the same may function as an etching booster.

In an implementation, the etching booster may include, e.g., monoammonium phosphate, diammonium phosphate, ammonium triphosphate, ammonium sulfate, ammonium bisulfate, ammonium persulfate, ammonium chloride, ammonium nitrite, ammonium fluoride, methyl methanesulfonate, ethanesulfonate, benzenesulfonate, ammonium sulfamate, ethylenediaminetetraacetic acid, iminodiacetic acid, diethylenetriaminepentaacetic acid, aminotrismethylenephosphonic acid, phosphorous acid, glycine, phenylphosphonic acid, sulfamic acid nitrotrismethylenephosphonic acid, 1-hydroxyethene-1,1-diphosphonic acid, dopamine, or adrenaline.

In an implementation, the etching booster may be included in an amount of, e.g., about 0.001 wt % to about 1 wt % in an etching composition. If the content of the etching booster were to be less than 0.001 wt %, an etching boosting effect could be reduced. If the content of the etching booster were to be greater than 1 wt %, the pH of the etching composition could increase undesirably. In an implementation, the etching booster may be included in an amount of about 0.001 wt % to about 1 wt % in the etching composition, and the etching composition may have high etching selectivity with respect to a metal-containing layer, e.g., a titanium aluminum nitride layer including aluminum with a high concentration.

In an implementation, the etching composition may include a residual or balance amount of a solvent. In an implementation, the solvent may include water. In an implementation, the solvent may be included in an amount of about 60 wt % to about 85 wt % in the etching composition.

In the etching composition according to example embodiments, an etching rate for etching a metal nitride may be relatively greater than an etching rate for etching a metal oxide (e.g., under otherwise identical, predetermined etching conditions). In an implementation, the etching composition according to example embodiments may have a first etching rate in an etching process for a metal nitride including a titanium nitride or a titanium aluminum nitride, and may have a second etching rate in an etching process for a metal oxide including a hafnium oxide, a zirconium oxide, or an aluminum oxide. In an implementation, the second etching rate may be in the range of about 0.1% to about 10% of the first etching rate.

In an implementation, in a structure in which a metal-containing layer (e.g., metal nitride layer) formed of a titanium nitride or a titanium aluminum nitride is formed on a metal oxide layer (including e.g., a hafnium oxide, a zirconium oxide, or an aluminum oxide), the etching composition may remove the metal-containing layer (e.g., metal nitride layer) at a sufficiently high speed while almost no damage or removal of the metal oxide layer when using the etching composition may occur. In an implementation, in an etching process using the etching composition, the amount of etching of a metal nitride layer may be relatively large, and there may be no or only a small amount of etching of the metal oxide layer when using the etching composition.

In an implementation, the etching composition may have a relatively high first etching rate for a titanium aluminum nitride including aluminum with a relatively high content, and the etching composition may have a relatively low second etching rate for both an aluminum oxide and a hafnium oxide. In an implementation, the etching composition may facilitate a selective etching process for a titanium aluminum nitride compared to an aluminum oxide and a hafnium oxide.

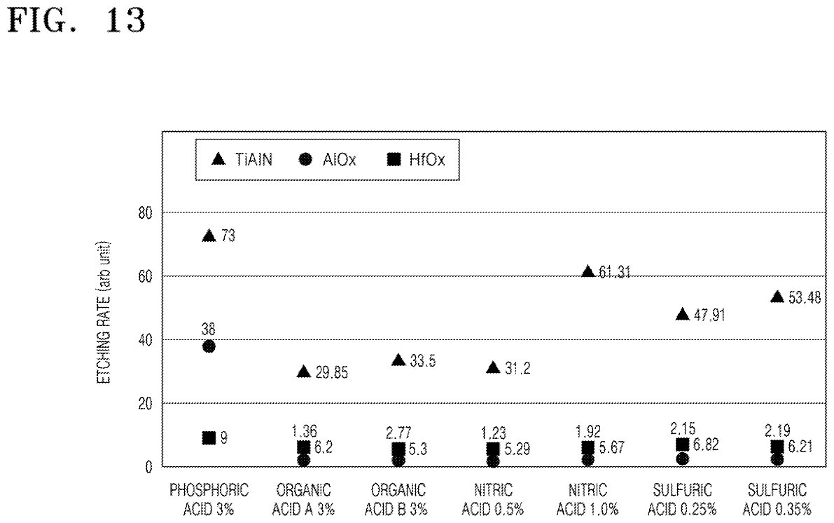

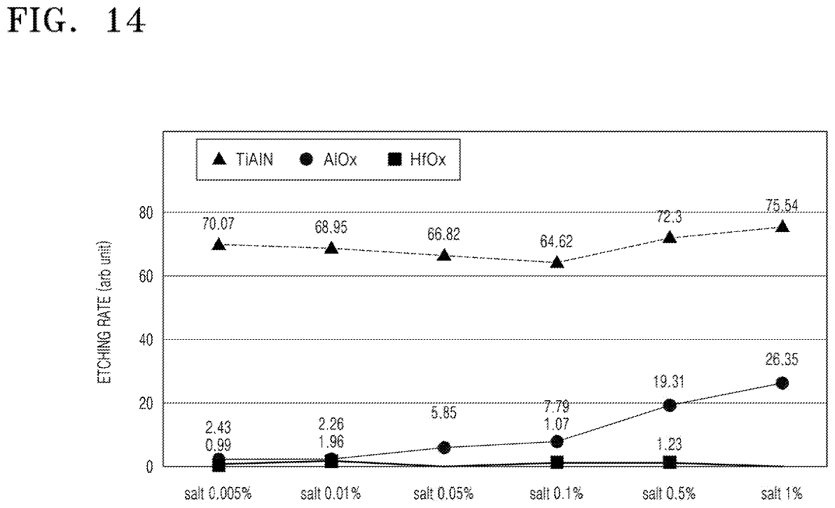

Hereinafter, etching selectivity characteristics of the etching compositions according to example embodiments will be described with reference to FIGS. 13 and 14.

### Experimental Example

FIG. 13 is a graph illustrating an etching rate using various etching compositions according to an experimental example. In an implementation, the etching compositions according to an experimental example each included hydrogen peroxide as an oxidizing agent and included various kinds of inorganic acids or organic acids described with reference to FIG. 13 as a pH adjusting agent.

Referring to FIG. 13, the various etching compositions according to the experimental example had a relatively high etching rate for a titanium aluminum nitride and had a relatively low etching rate for both a hafnium oxide and an aluminum oxide. It may be seen that, e.g., an etching composition including 3 wt % of phosphoric acid had a high etching rate for a titanium aluminum nitride and also had relatively high etching rates for an aluminum oxide and a hafnium oxide. This may cause a relatively high etching rate for the gate insulating layer 120 under the metal-containing layer 132 having a relatively high aluminum content, as described above.

FIG. 14 is a graph illustrating an etching rate using various etching compositions according to an experimental example. The etching compositions according to an experimental example each included hydrogen peroxide as an oxidizing agent, organic acid A as a pH adjusting agent, and phosphoric acid chelators of various contents.

Referring to FIG. 14, it may be seen that, when the content of a chelator (e.g., etching booster) was in the range of about 0.005 wt % to about 0.1 wt %, the etching composition had a high etching rate for a titanium aluminum nitride and had a significantly lower etching rate for an aluminum oxide and a hafnium oxide.

Hereinafter, a method of manufacturing an integrated circuit according to example embodiments, which includes an etching process using an etching composition according to example embodiments, will be described.

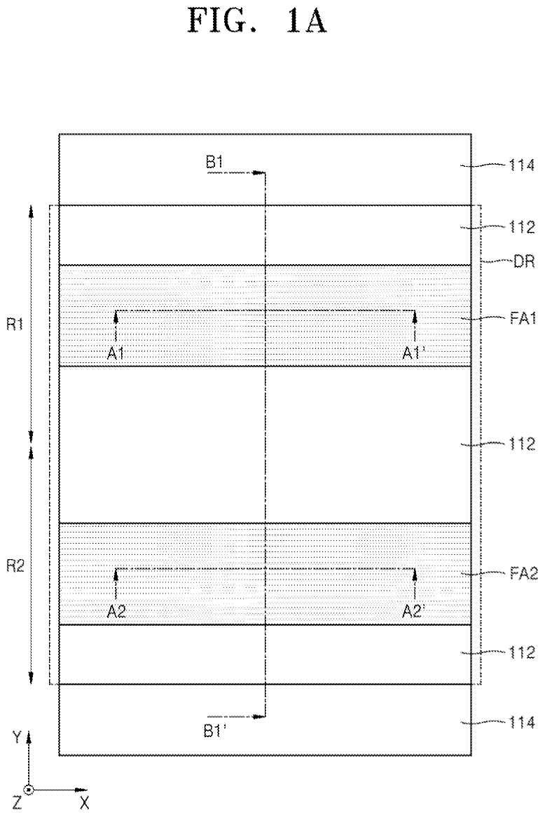

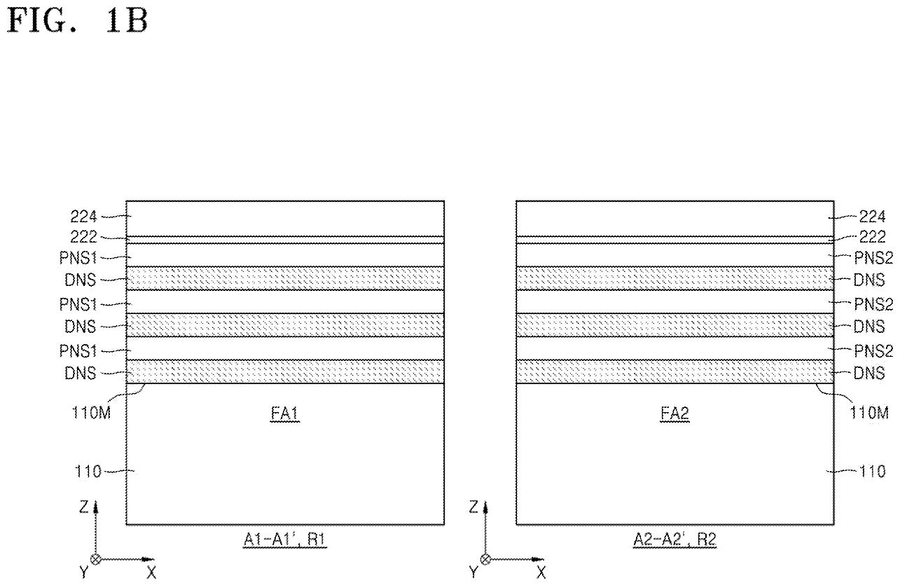

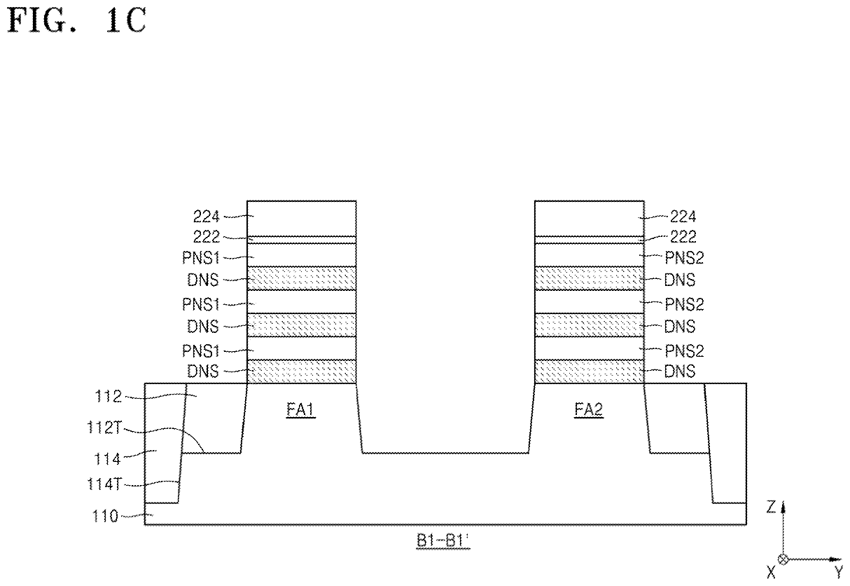

FIGS. 1A, 2A, 5A, and 12A are plan views of stages in manufacturing processes of an integrated circuit according to example embodiments, FIGS. 1B, 2B, 3, 4, 5B, 6A, 7A, 8A, 9A, 10A, 11A, and 12B are cross-sectional views taken along lines A1-A1′ and A2-A2′ of FIG. 1A, and FIGS. 1C, 2C, 6B, 7B, 8B, 9B, 10B, 11B, and 12C are cross-sectional views taken along line B1-B1′ of FIG. 1A.

Referring to FIGS. 1A, 1, and 1C, a substrate 110 may be provided. The substrate 110 may include a device region DR, and the device region DR may include a first region R1 and a second region R2. In an implementation, the first region R1 of the substrate 110 may be a region in which a first transistor is to be formed, and the second region R2 of the substrate 110 may be a region in which a second transistor is to be formed.

The substrate 110 may include a semiconductor, such as Si or Ge, or may include a compound semiconductor, such as SiGe, SiC, GaAs, InAs, or InP. In an implementation, the substrate 110 may be formed of a group III-V material or a group IV material. The group III-V material may include a binary, ternary, or quaternary compound including a group III element and a group V element. The group III-V material may be a compound including In, Ga, or A1 (a group III element), and As, P, or Sb (a group V element). In an implementation, the group III-V material may include InP, In_{z}Ga_{1-z}As (0≤z≤1), or Al_{z}Ga_{1-z}As (0≤z≤1). The binary compound may include, e.g., InP, GaAs, InAs, InSb, or GaSb. The ternary compound may include, e.g., InGaP, InGaAs, AlInAs, InGaSb, GaAsSb, or GaAsP. The group IV material may include, e.g., Si or Ge.

A sacrificial layer DNS, a first channel semiconductor layer PNS1, a second channel semiconductor layer PNS2 may be alternately and sequentially formed on an upper surface 110M of the substrate 110. The sacrificial layer DNS, the first channel semiconductor layer PNS1, and the second channel semiconductor layers PNS2 may be formed by an epitaxial process.

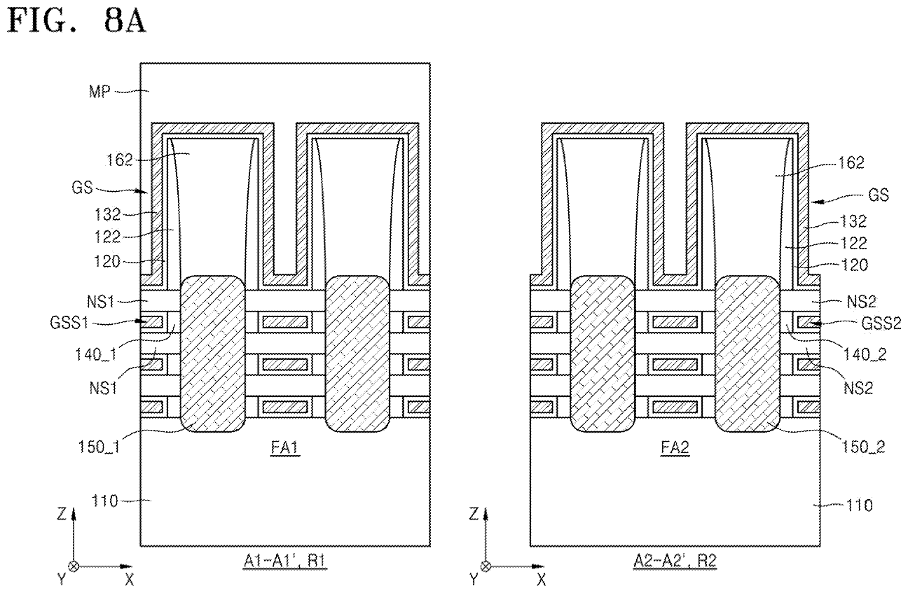

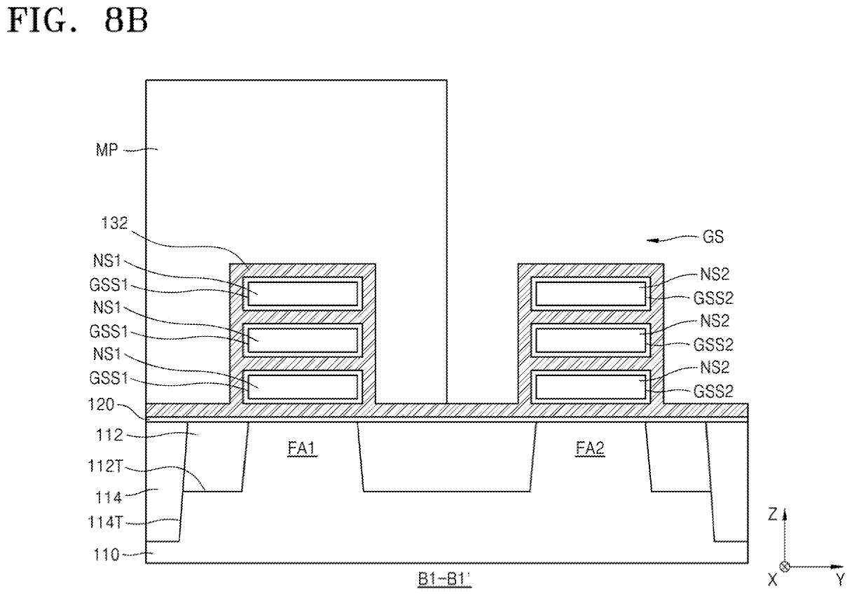

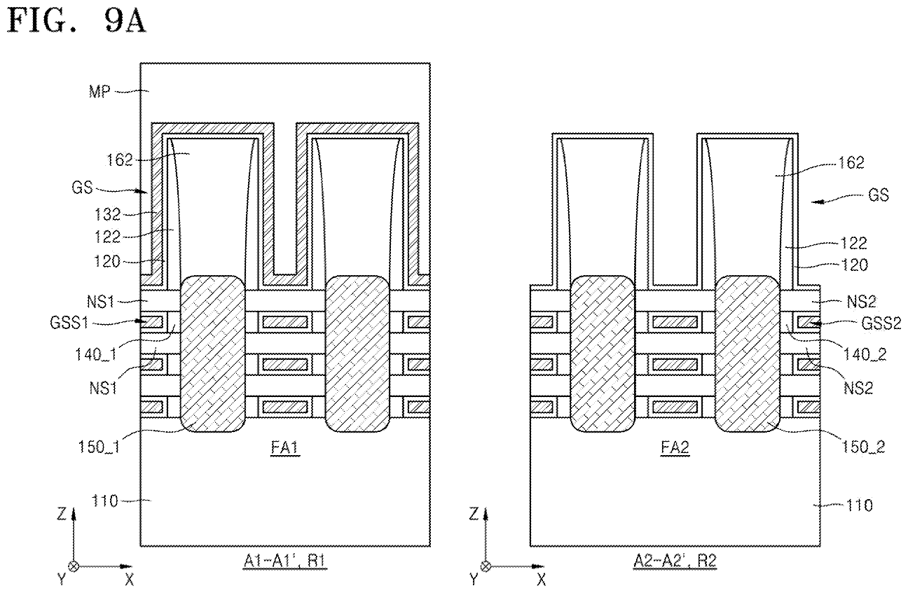

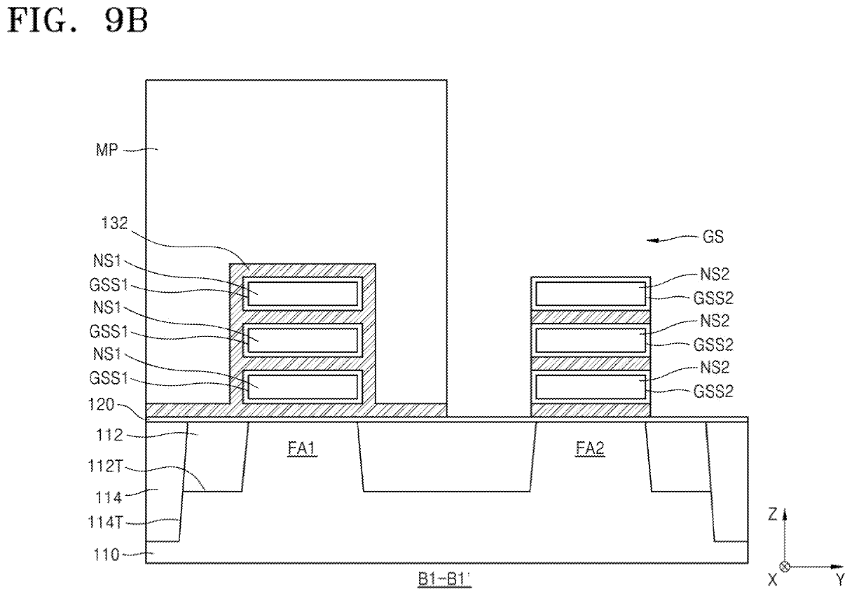

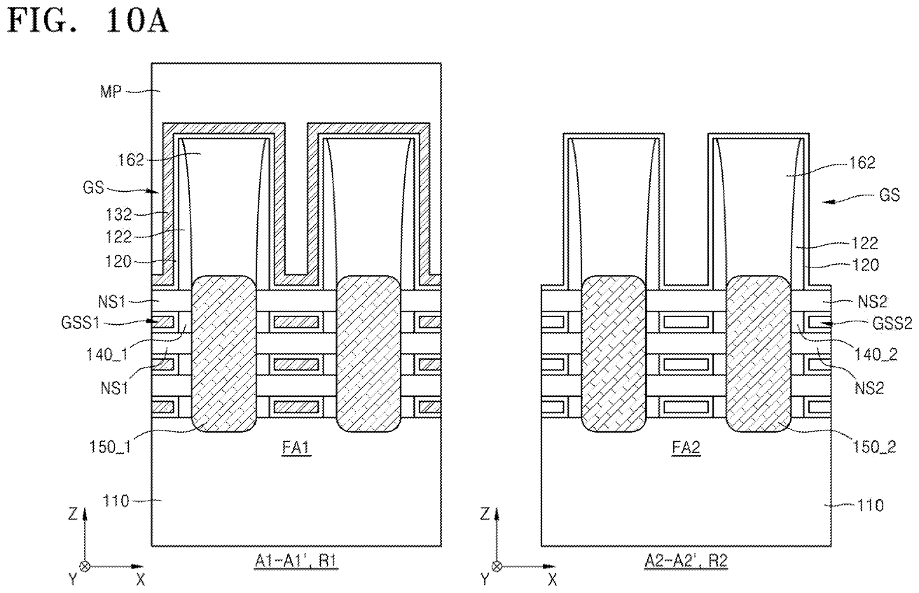

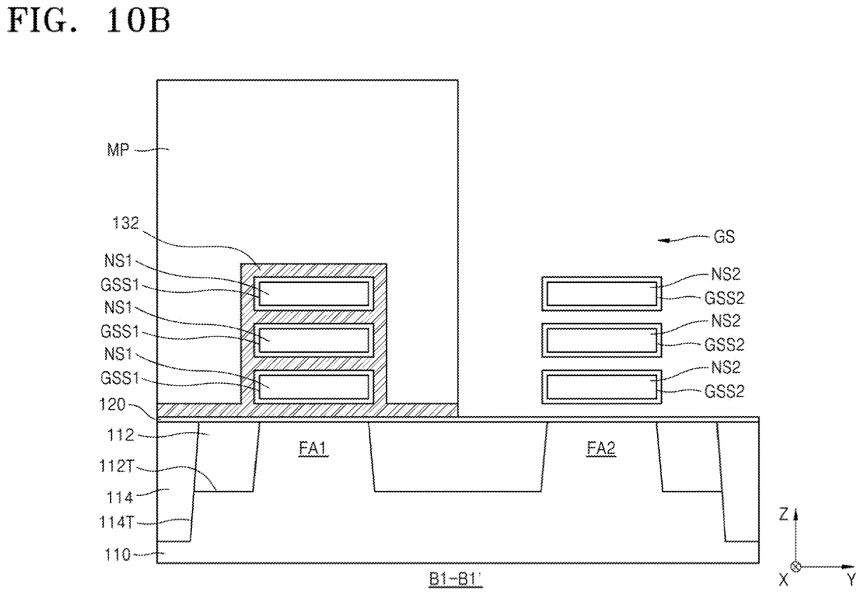

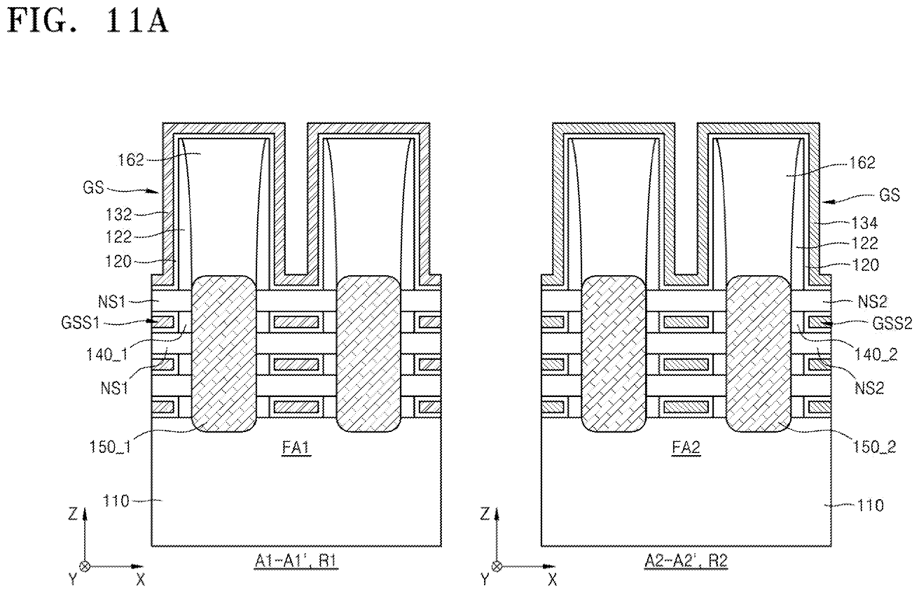

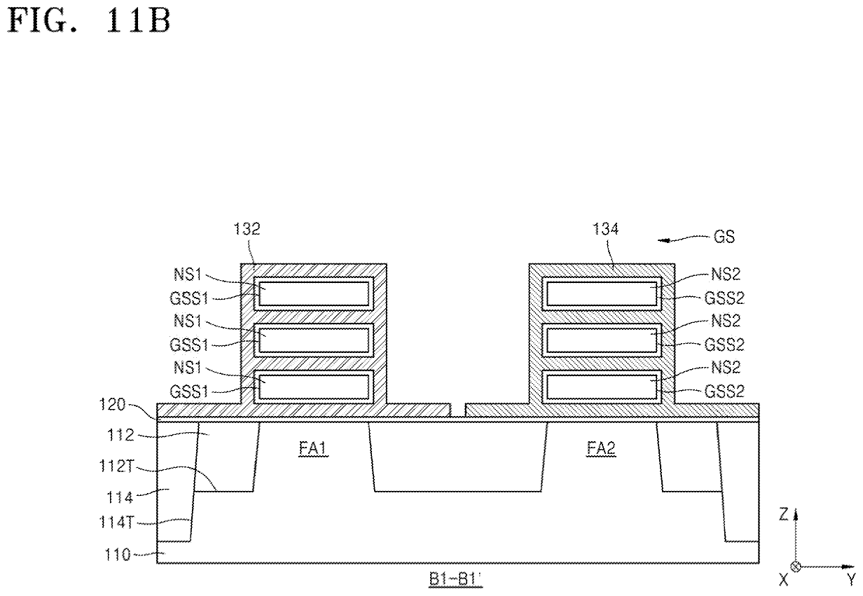

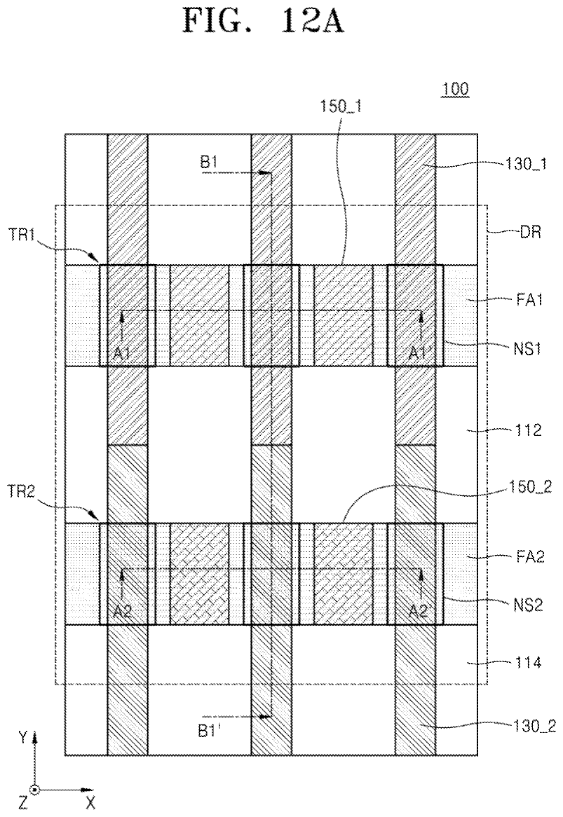

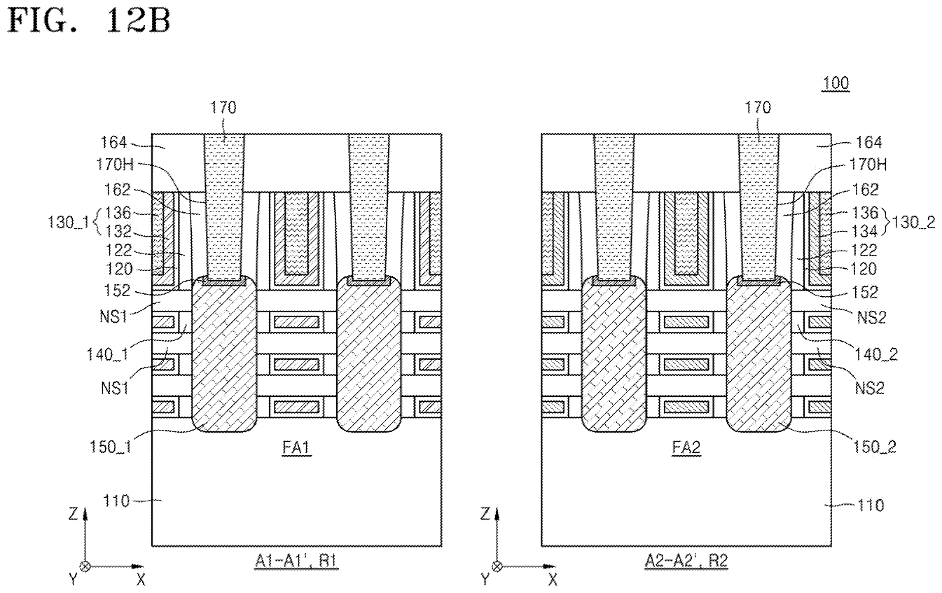

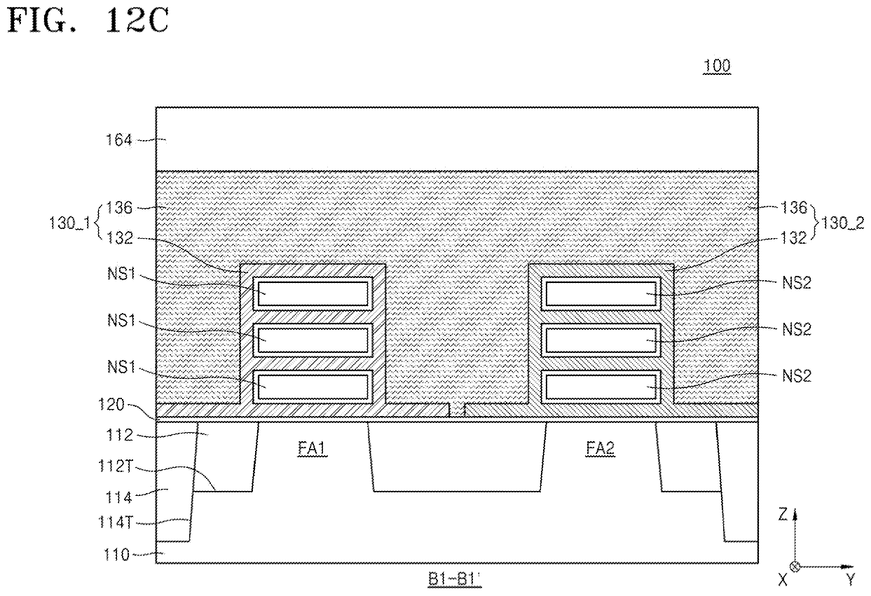

The first channel semiconductor layer PNS1 may be formed on a region of the substrate 110 in which a first transistor TR1 (see FIG. 12A) is to be formed, and the second channel semiconductor layer PNS2 may be formed on a region of the substrate 110 in which the second transistor TR2 (see FIG. 12A) is to be formed. In an implementation, the first channel semiconductor layer PNS1 and the second channel semiconductor layer PNS2 may be formed in the same process to constitute one material layer connected to each other. In an implementation, the first channel semiconductor layer PNS1 may be formed first, and then the second channel semiconductor layer PNS2 may be formed.

In an implementation, the sacrificial layer DNS and the first and second channel semiconductor layers PNS1 and PNS2 may be formed of a material with an etching selectivity to each other. In an implementation, the sacrificial layer DNS, the first channel semiconductor layer PNS1, and the second channel semiconductor layer PNS2 may each be composed of a single crystal layer of a group IV semiconductor, an oxide semiconductor, or a group III-V compound semiconductor, and the sacrificial layer DNS, the first channel semiconductor layer PNS1, and the second channel semiconductor layer PNS2 may be formed of different materials. In an implementation, the sacrificial layer DNS may be formed of SiGe, and the first channel semiconductor layer PNS1 and the second channel semiconductor layer PNS2 may be formed of single crystal silicon.

In an implementation, an epitaxy process may be a chemical vapor deposition (CVD) process, e.g., vapor-phase epitaxy (VPE) or ultra-high vacuum chemical vapor deposition (UHV-CVD), molecular beam epitaxy, or a combination thereof. In the epitaxy process, a liquid or gaseous precursor may be used as a precursor to form the sacrificial layer DNS, the first channel semiconductor layer PNS1, and the second channel semiconductor layer PNS2.

Thereafter, a lower layer 222 and a hard mask pattern 224 extending to a preset length in a first direction (the X direction) may be formed on the first channel semiconductor layer PNS1 and the second channel semiconductor layer PNS2, and then the sacrificial layer DNS, the first channel semiconductor layer PNS1, the second channel semiconductor layer PNS2, and the substrate 110 may be etched by using the lower layer 222 and the hard mask pattern 224 as an etching mask to form a sacrificial pattern and an device isolation trench 112T.

Thereafter, the device isolation layer 112 may be filled in the device isolation trench 112T, and an upper portion of the device isolation layer 112 may be planarized. A part of the device isolation layer 112 and a part of the substrate 110 may be etched to form a deep trench 114T defining the device region DR, and a deep trench insulating layer 114 may be formed inside the deep trench 114T.

Thereafter, the lower layer 222 and the hard mask pattern 224 that remained on the sacrificial layer pattern may be removed, and a recess process may be performed to remove partial thicknesses of the device isolation layer 112 and the deep trench insulating layer 114 from upper portions thereof.

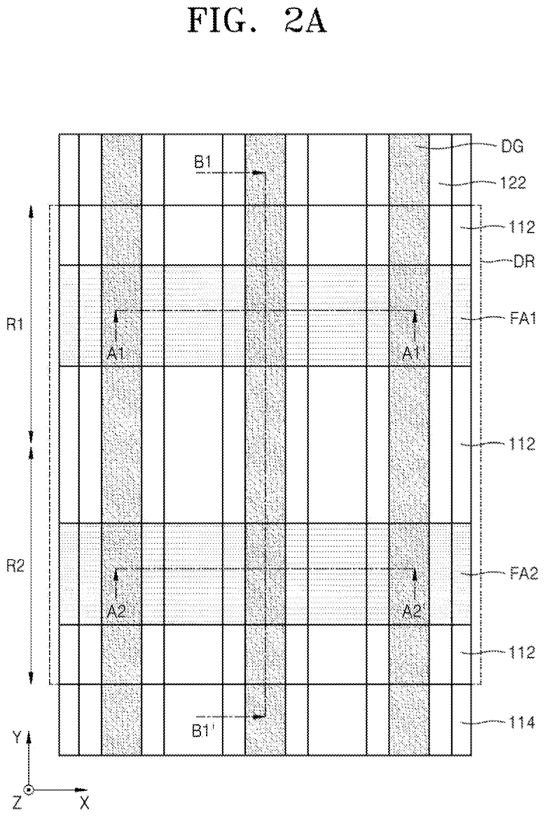

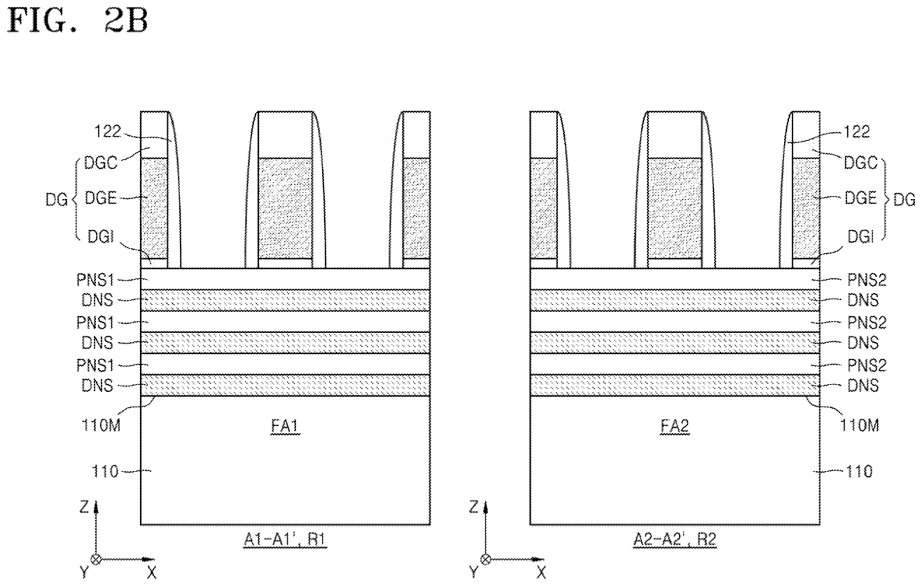

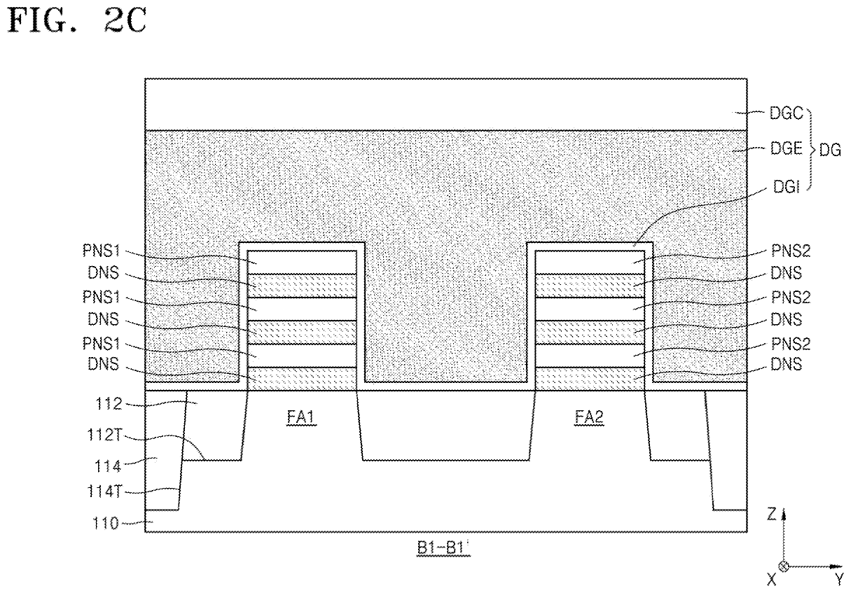

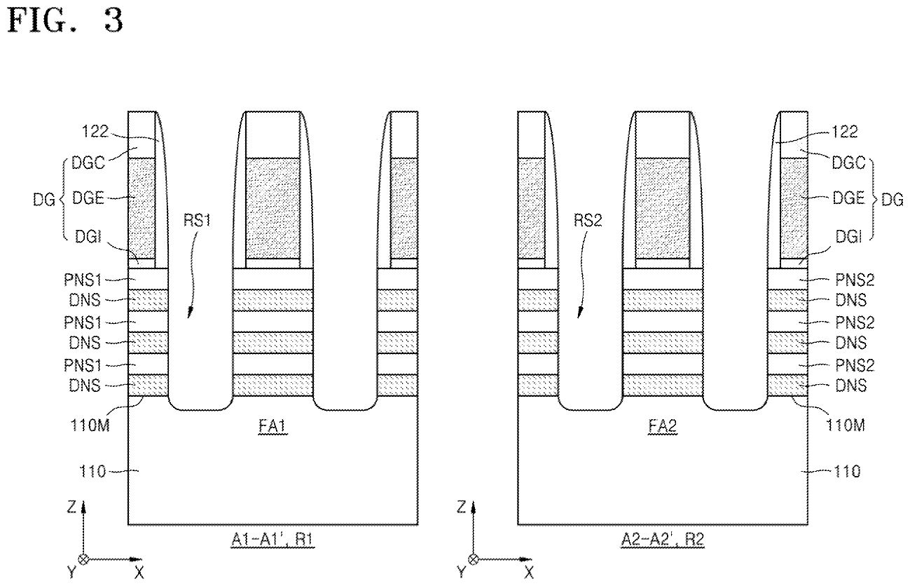

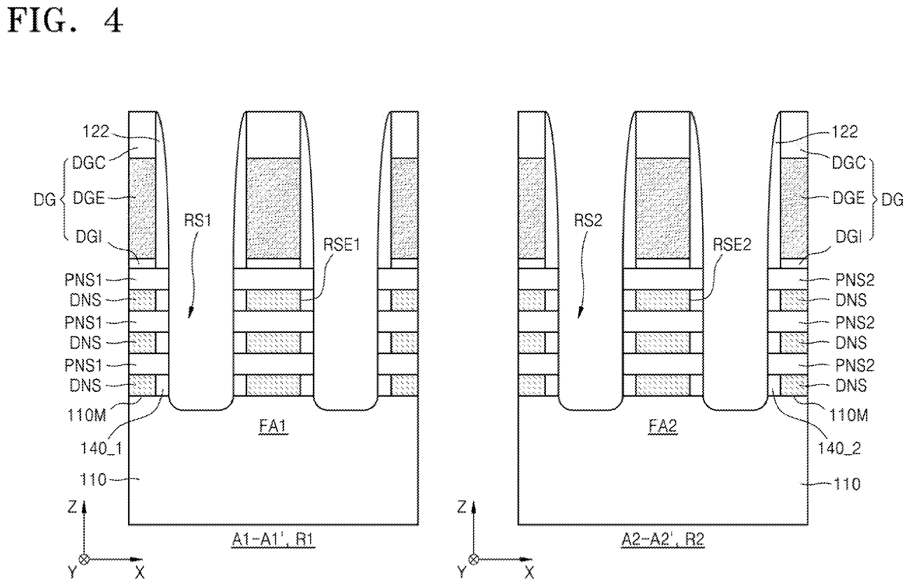

Referring to FIGS. 2A, 2B, and 2C, a dummy gate structure DG may be formed on the sacrificial layer pattern and the device isolation layer 112. The dummy gate structure DG may include a dummy gate insulating layer DGI, a dummy gate electrode DGE, and a dummy gate capping layer DGC.

In an implementation, the dummy gate electrode DGE may be formed of polysilicon, and the dummy gate capping layer DGC may be formed of a silicon nitride layer. The dummy gate insulating layer DGI may be formed of a material with an etching selectivity to the dummy gate electrode DGE and may be formed of, e.g., a thermal oxide, a silicon oxide, or a silicon nitride.

The dummy gate structure DG may be formed to extend in a second horizontal direction Y to cross the first region R1 and the second region R2, and the dummy gate electrode DGE may be formed to have a relatively great thickness to cover a sacrificial layer pattern including the first channel semiconductor layer PNS1 and the sacrificial layer DNS and a sacrificial layer pattern including the second channel semiconductor layer PNS2 and the sacrificial layer DNS.

Gate spacers 122 may be formed on both sidewalls of the dummy gate structure DG. The gate spacers 122 may each be formed of a silicon oxide, a silicon oxynitride, or a silicon nitride, and may extend in an extension direction of the dummy gate structure DG, for example, in the second horizontal direction Y.

Referring to FIG. 3, the sacrificial layer pattern on both sides of the dummy gate structure DG and a part of the substrate 110 may be etched to form a first recess RS1 and a second recess RS2 on both sides of the dummy gate structure DG. The sacrificial layer DNS and sidewalls of the first and second channel semiconductor layers PNS1 and PNS2 may be exposed on inner walls of the first recess RS1 and the second recess RS2.

Referring to FIG. 4, a part of the sacrificial layer DNS exposed on inner walls of the first recess RS1 and the second recess RS2 may be removed laterally by using an isotropic etching process to form the recess regions RSE1 and RSE2. In an implementation, the removal process may include a wet etching process. In an implementation, the sacrificial layer DNS including SiGe may be etched faster than the first and second channel semiconductor layers PNS1 and PNS2 including, e.g., Si, and thus, the recess regions RSE1 and RSE2 may be formed.

Thereafter, an insulating layer that fills the recess regions RSE1 and RSE2 may be formed on inner walls of the first recess RS1 and the second recess RS2, and only the insulating layer in the recess region may remain, the other unnecessary insulating layer may be removed, and accordingly, a first inner spacer 140_1 and a second inner spacer 140_2 may be formed.

In an implementation, the first inner spacer 140_1 may be at a position that vertically overlaps the gate spacer 122 between two adjacent first channel semiconductor layers PNS1 among a plurality of first channel semiconductor layers PNS1. In addition, the second inner spacer 140_2 may be at a position that vertically overlaps the gate spacer 122 between two adjacent second channel semiconductor layers PNS2 among the plurality of second channel semiconductor layers PNS2.

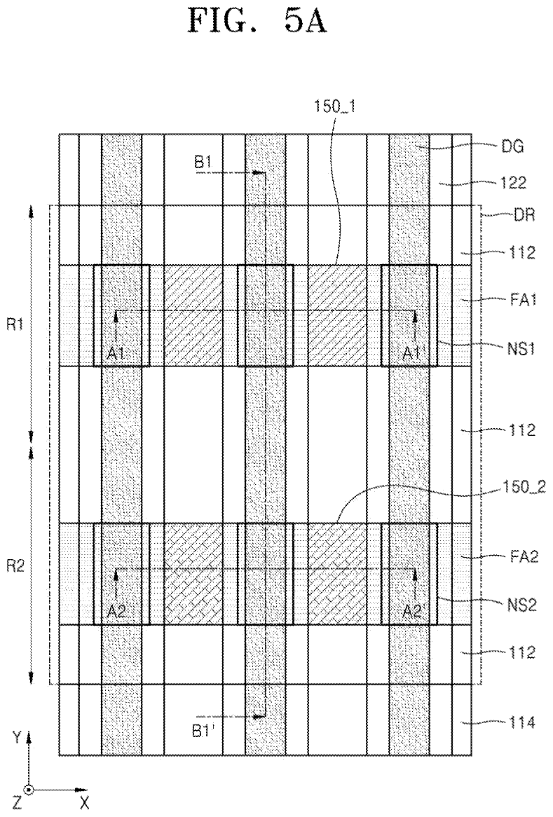

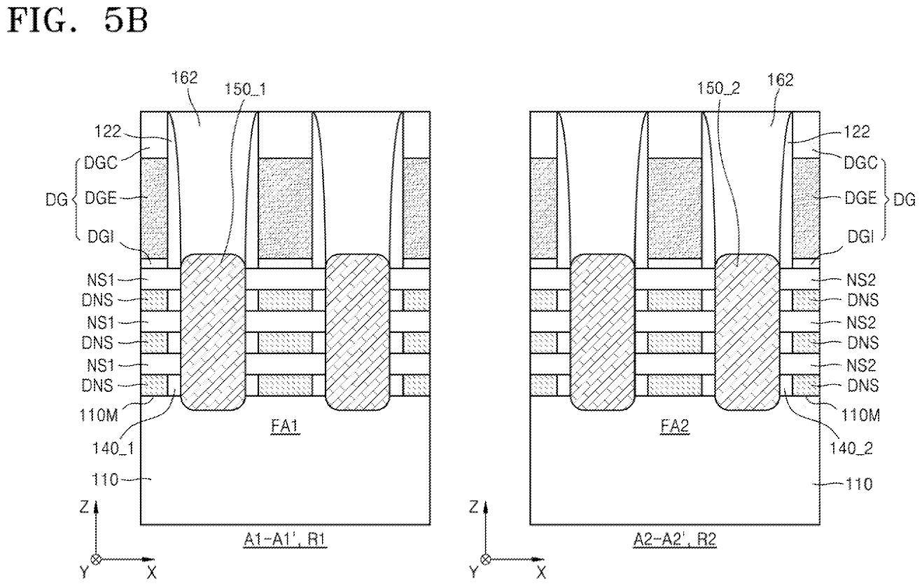

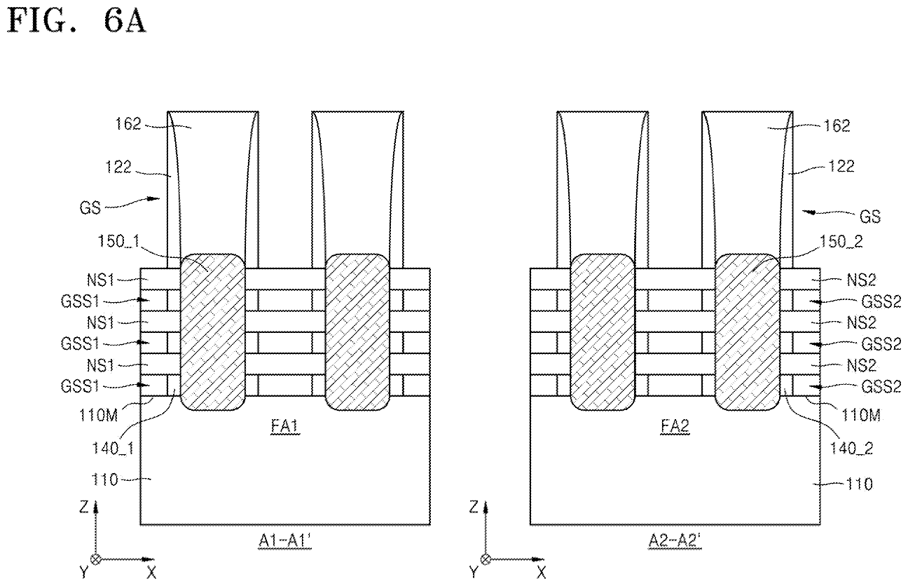

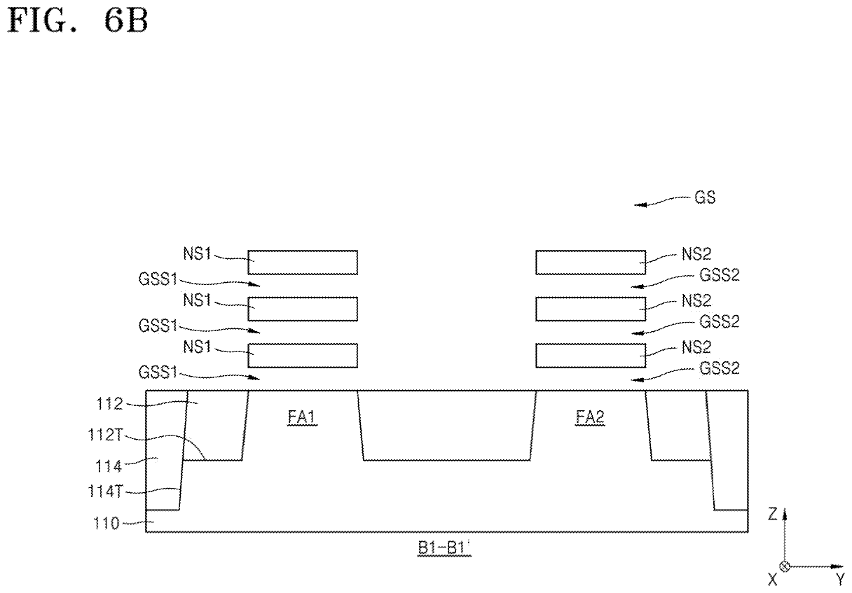

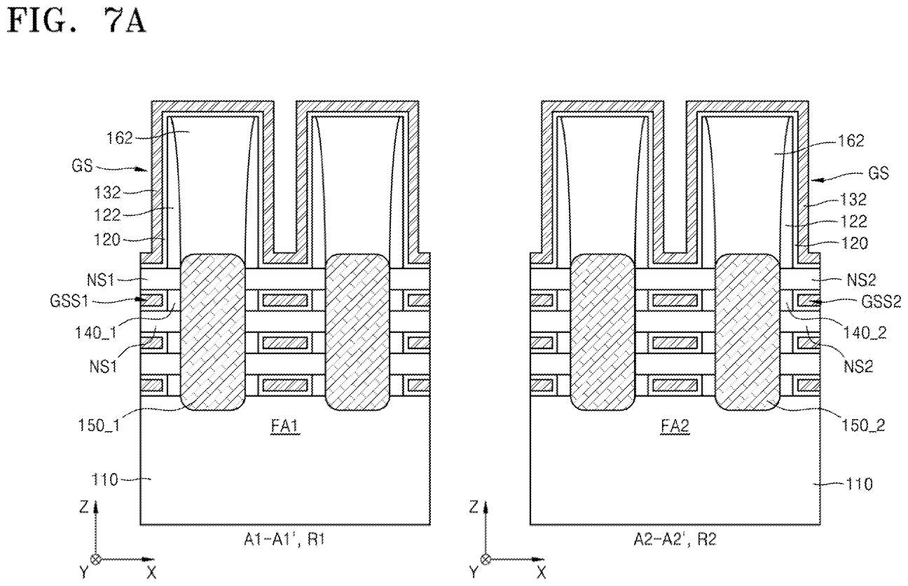

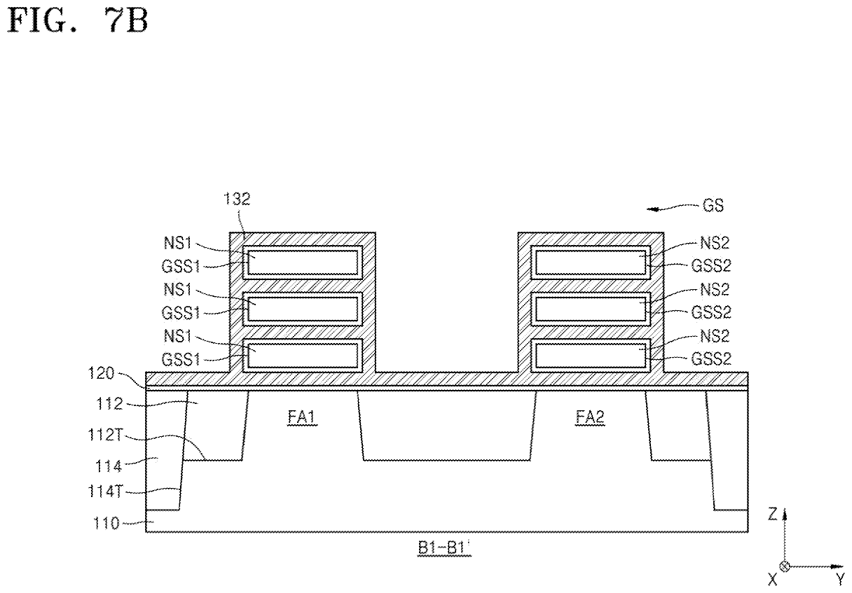

Referring to FIGS. 5A and 5B, a first semiconductor layer 150_1 and a second semiconductor layer 150_2 may be respectively formed in the first recess RS1 and the second recess RS2. In an implementation, the first semiconductor layer 150_1 may be formed by epitaxially growing a semiconductor material from the surface of the first channel semiconductor layer PNS1 exposed on the inner wall of the first recess RS1 and the substrate 110. In an implementation, the second semiconductor layer 150_2 may be formed by epitaxially growing a semiconductor material from the second channel semiconductor layer PNS2 and a surface of the substrate 110 exposed on the inner wall of the second recess RS2.

In an implementation, the first recess RS1 and the second recess RS2 may be formed respectively and simultaneously in a first fin-type active region FA1 and a second fin-type active region FA2, and the first semiconductor layer 150_1 and the second semiconductor layer 150_2 may be simultaneously formed. In an implementation, after a protective layer is formed on the second fin-type active region FA2, the first recess RS1 and the first semiconductor layer 150_1 are first formed, and then another protective layer may be formed on the first fin-type active region FA1, and the second recess RS2 and the second semiconductor layer 150_2 may be formed. In this case, a material included in the first semiconductor layer 150_1 may be different from a material included in the second semiconductor layer 150_2.

Thereafter, an inter-gate insulating layer 162 may be formed on a sidewall of the dummy gate structure DG, the first semiconductor layer 150_1, and the second semiconductor layer 150_2.

Here, the first channel semiconductor layer PNS1 on the first fin-type active region FA1 may be referred to as a plurality of first semiconductor patterns NS1, and the second channel on the second fin-type active region FA2 may be referred to as a plurality of second semiconductor patterns NS2. Both ends of the plurality of first semiconductor patterns NS1 in the first horizontal direction X may be connected to the first semiconductor layer 150_1 and both ends of the plurality of second semiconductor patterns NS2 in the first horizontal direction X may be connected to the second semiconductor layer 150_2. In an implementation, the sacrificial layer DNS and the first inner spacer 140_1 may be between two adjacent first semiconductor patterns NS1 among the plurality of first semiconductor patterns NS1, and the sacrificial layer DNS and the second inner spacer 140_2 may be between two adjacent second semiconductor patterns NS2 among the plurality of second semiconductor patterns NS2.

Referring to FIGS. 6A and 6B, the dummy gate capping layer DGC (see FIG. 8) of the dummy gate structure DG may be removed by planarizing upper portions of the dummy gate structure DG and the inter-gate insulating layer 162, and thus, an upper surface of the dummy gate electrode DGE may be exposed.

Thereafter, a gate space GS may be formed by removing the dummy gate electrode DGE and the dummy gate insulating layer DGI exposed through the inter-gate insulating layer 162. In the removal process, the gate spacer 122 may remain, and the gate space GS may be defined by both sidewalls of the gate spacer 122.

Thereafter, a plurality of sacrificial layers DNS on the first and second fin-type active regions FA1 and FA2 may be removed through the gate space GS to partially expose the plurality of first semiconductor pattern NS1, the plurality of second semiconductor patterns NS2, and upper surfaces of the first and second fin-type active regions FA1 and FA2 through the gate space GS.

As the sacrificial layer DNS is removed, first sub-gate spaces GSS1 may be formed between the plurality of first semiconductor patterns NS1 and second sub-gate spaces GSS2 may be formed between the plurality of second semiconductor patterns NS2.

The removal process of a plurality of sacrificial layers DNS may include a wet etching process using a difference in etching selectivity between the plurality of sacrificial layers DNS and the plurality of first semiconductor patterns NS1 and a difference in etching selectivity between the plurality of sacrificial layers DNS and the plurality of second semiconductor patterns NS2.

Referring to FIGS. 7A and 7B, the gate insulating layer 120 may be formed on surfaces exposed in the gate space GS and the first and second sub-gate spaces GSS1 and GSS2. The gate insulating layer 120 may be formed to surround upper surfaces, bottom surfaces, and sidewalls of the plurality of first semiconductor patterns NS1 and to surround upper surfaces, bottom surfaces, and sidewalls of the plurality of second semiconductor patterns NS2 and may also be formed on an upper surface of the first fin-type active region FA1, an upper surface of the second fin-type active region FA2, the device isolation layer 112, and the deep trench insulating layer 114.

In an implementation, the gate insulating layer 120 may have a stacked structure of an interfacial layer and a high-k layer. The interfacial layer may remove interface defects between high-k layers on the upper surfaces of the fin-type active regions FA1 and FA2 and surfaces of the plurality of first and second semiconductor patterns NS1 and NS2.

In an implementation, the interfacial layer may be composed of a low-k layer with permittivity of about 9 or less, e.g., a silicon oxide layer, a silicon oxynitride layer, a Ga oxide layer, a Ge oxide layer, or a combination thereof. In an implementation, the interfacial layer may be formed of silicate, a combination of silicate and a silicon oxide, or a combination of silicate and a silicon oxynitride. In an implementation, the interfacial layer may be omitted.

The high-k layer may be formed of a material with higher permittivity than the permittivity of a silicon oxide. In an implementation, the high-k layer may have a dielectric constant of about 10 to about 25. The high-k layer may be formed of, e.g., a hafnium oxide, a hafnium oxynitride, a hafnium silicon oxide, a lanthanum oxide, a lanthanum aluminum oxide, a zirconium oxide, a zirconium silicon oxide, a tantalum oxide, a titanium oxide, a barium strontium titanium oxide, a barium titanium oxide, a strontium titanium oxide, an yttrium oxide, an aluminum oxide, a lead scandium tantalum oxide, a lead zinc niobate, or combinations thereof. The high-k layer may be formed by an atomic layer deposition (ALD) process, a CVD process, or a physical vapor deposition (PVD) process. The high-k layer may have a thickness of, e.g., about 10 Å to about 40 Å.

Thereafter, a metal-containing layer 132 may be conformally formed on the gate insulating layer 120. In an implementation, the metal-containing layer 132 may have a thickness sufficient to completely fill the first sub-gate space GSS1 between the plurality of first semiconductor patterns NS1 and the second sub-gate space GSS2 between the plurality of second semiconductor patterns NS2. In an implementation, the metal-containing layer 132 may also be conformally formed to have a thickness that does not completely fill the first sub-gate space GSS1 between the plurality of first semiconductor patterns NS1 and may not completely fill the second sub-gate space GSS2 between the plurality of second semiconductor patterns NS2.

In an implementation, the metal-containing layer 132 may include a metal nitride and may include, e.g., a titanium nitride or a titanium aluminum nitride. In an implementation, the metal-containing layer 132 may include a titanium aluminum nitride having a relatively high aluminum content. In an implementation, the metal-containing layer 132 may include a titanium aluminum nitride including greater than 10 at % of aluminum (e.g., based on a total number of atoms in the titanium aluminum nitride). In an implementation, the metal-containing layer 132 may include a titanium aluminum nitride including 10 at % to 20 at %, or 15 at % to 30 at % of aluminum.

Referring to FIGS. 8A and 8B, a mask pattern MP covering the first region R1 of the substrate 110 may be formed on the metal-containing layer 132. In an implementation, the mask pattern MP may cover a part of the metal-containing layer 132 surrounding the plurality of first semiconductor patterns NS1 and may not cover a part of the metal-containing layer 132 surrounding the plurality of second semiconductor patterns NS2. In an implementation, the mask pattern MP may fill in the gate space GS and cover a part of the device isolation layer 112.

In an implementation, the mask pattern MP may include a carbon insulating material. In an implementation, the mask pattern MP may be formed of a material with a relatively high carbon content. In an implementation, the mask pattern MP may include, e.g., SiC:H, SiCN, SiCN:H, SiOCN, SiOCN:H, silicon oxycarbide (SiOC), a spin on hardmask (SOH), Si-containing anti-reflective coating (ARC), spin on glass (SOG), an advanced planarization layer (APL), an organic dielectric layer (ODL), or the like.

Here, a portion of the metal-containing layer 132 surrounding the plurality of first semiconductor patterns NS1 may be referred to as a first portion of the metal-containing layer 132, and a portion of the metal-containing layer 132 surrounding the plurality of second semiconductor patterns NS2 may be referred to as a second portion of the metal-containing layer 132.

Referring to FIGS. 9A and 9B, the second portion of the metal-containing layer 132 on the second region R2 of the substrate 110 may be removed by an etch-back process. In an implementation, a portion of the metal-containing layer 132 in the gate space GS on the second region R2 of the substrate 110 may be removed. In an implementation, a portion of the metal-containing layer 132 on an upper portion of the uppermost second semiconductor pattern NS2 and on the device isolation layer 112 may be removed, and a portion of the metal-containing layer 132 on sidewalls of each of the plurality of second semiconductor patterns NS2 may be removed.

During the etch-back process, portions of the metal-containing layer 132 which are provided in the plurality of second sub-gate spaces GSS2 may not be damaged or removed.

Referring to FIGS. 10A and 10B, the second portions of the metal-containing layer 132 in the second sub-gate spaces GSS2 between the plurality of second semiconductor patterns NS2 may be removed. In an implementation, a portion of the metal-containing layer 132 between two adjacent second semiconductor patterns NS2 among the plurality of second semiconductor patterns NS2 may be removed through, e.g., a lateral etching process.

In an implementation, the etching process for removing the second portions of the metal-containing layer 132 described with reference to FIGS. 10A and 10B may be an etching process using an etching composition according to example embodiments. In an implementation, the etching composition may include an oxidizing agent in an amount of about 15 wt % to about 30 wt %, a pH adjusting agent including an inorganic or organic acid in an amount of about 1 wt % to about 10 wt %, an etching booster in an amount of about 0.001 wt % to about 1 wt %, and a solvent.

In the etching composition according to example embodiments, an etching rate for etching a metal nitride may be relatively greater than an etching rate for etching a metal oxide. In an implementation, in an etching process using an etching composition according to example embodiments, the metal-containing layer 132 may be removed at a first etching rate, and the gate insulating layer 120 may be removed at a second etching rate which may be, e.g., about 0.1% to about 10% of the first etching rate. In an implementation, in the etching process, the mask pattern MIP may be removed at a third etching rate of, e.g., about 0.1% to about 10% of the first etching rate.

In an implementation, when the metal-containing layer 132 is formed of a titanium aluminum nitride including aluminum with a relatively high content, aluminum atoms included in the metal-containing layer 132 may be diffused to move to an interface between the gate insulating layer 120 and the metal-containing layer 132, or the aluminum atoms may be diffused to move into the gate insulating layer 120. In an implementation, when the gate insulating layer 120 includes a hafnium oxide, a surface region including an aluminum oxide or a hafnium aluminum oxide may be locally formed in the gate insulating layer 120 adjacent to the interface between the gate insulating layer 120 and the metal-containing layer 132. If other etching compositions were to be used to etch the metal-containing layer 132, a surface region of the gate insulating layer 120 may be removed at a relatively high etching rate, and thus, etching selectivity of the metal-containing layer 132 may be reduced, and quality of the gate insulating layer 120 may be reduced after the etching process.

However, according to example embodiments, the etching composition may have a relatively high first etching rate for a titanium aluminum nitride including aluminum with a relatively high content, and the etching composition may have a relatively low second etching rate for both an aluminum oxide and a hafnium oxide. Accordingly, in the etching process for removing the metal-containing layer 132, the amount of removal of a surface region of the gate insulating layer 120 under the metal-containing layer 132 may be little or insignificant, and thus, the gate insulating layer 120 may maintain excellent quality.

In an implementation, an etching process of partially removing the metal-containing layer 132 between two adjacent second semiconductor patterns NS2 among the plurality of second semiconductor patterns NS2 may be performed at a relatively high etching rate, and in the process of performing the etching process, partial removal or surface damage of the gate insulating layer 120 on the uppermost second semiconductor pattern NS2 or the gate insulating layer 120 relatively exposed to the etching process for a long time may be greatly reduced.

Referring to FIGS. 11A and 111B, a conductive layer 134 covering the plurality of second semiconductor patterns NS2 may be formed. In an implementation, the conductive layer 134 may be formed of, e.g., Al, Cu, Ti, Ta, W, Mo, TaN, NiSi, CoSi, TiN, WN, TiAl, TiAlC, TiAlN, TaCN, TaC, TaSiN, or a combination thereof. In an implementation, the conductive layer 134 may be a single layer or a double layer. In an implementation, the conductive layer 134 may have a thickness sufficient to completely fill the second sub-gate space GSS2 between the plurality of second semiconductor patterns NS2.

In an implementation, the conductive layer 134 may be formed on the second region R2 of the substrate 110 in a state in which the plurality of first semiconductor patterns NS1 are covered by the mask pattern MP. In an implementation, the mask pattern MP may be removed before the conductive layer 134 is formed, the conductive layer 134 may be formed in both the first region R1 and the second region R2 of the substrate 110, and in this case, the conductive layer 134 may be formed on the metal-containing layer 132 in the gate space GS in the first region R1 of the substrate 110, e.g., on an upper surface of the uppermost first semiconductor pattern NS1.

Referring to FIGS. 12A, 12B, and 12C, a buried conductive layer 136 may be formed on the metal-containing layer 132 and the conductive layer 134. The buried conductive layer 136 may be formed of, e.g., Al, Cu, Ti, Ta, W, Mo, TaN, NiSi, CoSi, TiN, WN, TiAl, TiAlC, TiAlN, TaCN, TaC, TaSiN, or a combination thereof.

Thereafter, a first gate structure 130_1 and a second gate structure 130_2 may be formed by planarizing an upper portion of the buried conductive layer 136 such that an upper surface of the inter-gate insulating layer 162 is exposed. The first gate structure 130_1 may include the metal-containing layer 132 and the buried conductive layer 136 surrounding the plurality of first semiconductor patterns NS1 on the first fin-type active region FA1. The second gate structure 130_2 may include the conductive layer 134 and the buried conductive layer 136 surrounding the plurality of second semiconductor patterns NS2 on the second fin-type active region FA2.

The first fin-type active region FA1, the plurality of first semiconductor patterns NS1, and the first gate structure 130_1 may constitute the first transistor TR1, and the second fin-type active region FA2, the plurality of second semiconductor patterns NS2, and the second gate structure 130_2 may constitute the second transistor TR2.

In an implementation, the first transistor TR1 may include a PMOS transistor, and the second transistor TR2 may include an NMOS transistor. In an implementation, the first transistor TR1 may include a PMOS transistor having a first threshold voltage, and the second transistor TR2 may include a PMOS transistor having a second threshold voltage that is different from the first threshold voltage. In an implementation, the first transistor TR1 may include an NMOS transistor having the first threshold voltage, and the second transistor TR2 may include an NMOS transistor having the second threshold voltage that is different from the first threshold voltage.

In an implementation, each of the plurality of first semiconductor patterns NS1 may have a width in the range of about 5 to about 100 nm in the second horizontal direction Y, and each of the plurality of first semiconductor patterns NS1 may have a thickness in the range of about 1 to about 10 nm in the vertical direction Z. The plurality of first semiconductor patterns NS1 may function as a channel region of the first transistor TR1 and may be referred to as a multi-bridge channel. In an implementation, each of the plurality of second semiconductor patterns NS2 may have a width in the range of about 5 to about 100 nm in the second horizontal direction Y, and each of the plurality of second semiconductor patterns NS2 may have a thickness in the range of about 1 to about 10 nm in the vertical direction Z. The plurality of second semiconductor patterns NS2 may function as a channel region of the second transistor TR2 and may be referred to as a multi-bridge channel.

Thereafter, an upper insulating layer 164 may be formed on the first and second gate structures 130_1 and 130_2 and the inter-gate insulating layer 162. Thereafter, a contact hole 170H may be formed through the upper insulating layer 164 and the inter-gate insulating layer 162 to expose upper surfaces of the first semiconductor layer 1501 and the second semiconductor layer 150_2. A metal silicide layer 152 may be formed on the upper surfaces of the first semiconductor layer 1501 and the second semiconductor layer 150_2 exposed at the bottom of the contact hole 170H, and a contact plug 170 may be formed in the contact hole 170H by using a conductive material. In an implementation, the metal silicide layer 152 may include titanium silicide, nickel silicide, tungsten silicide, or cobalt silicide, and the contact plug 170 may include a titanium nitride, a tantalum nitride, tungsten, aluminum, cobalt, or copper.

The integrated circuit 100 may be manufactured by performing the processes described above.

According to example embodiments, a part of the metal-containing layer 132 may be selectively removed by an etching process using an etching composition with high etching selectivity with respect to the metal-containing layer 132, and thus, damage or removal of the gate insulating layer 120 under the metal-containing layer 132 may be prevented in the etching process. Accordingly, the integrated circuit 100 may have excellent electrical performance.

By way of summation and review, a short-channel effect of a transistor could occur due to the downscaling of an integrated circuit, and accordingly, the reliability of the integrated circuit could be reduced. In order to reduce the short-channel effect, an integrated circuit having a multi-gate structure, e.g., a nanosheet-type transistor, has been considered. An etching composition having a high etching selectivity between an etching target layer and another layer may be used in a process of manufacturing an integrated circuit.

One or more embodiments may provide an etching composition used for etching a metal nitride layer.

One or more embodiments may provide an etching composition with a high etching selectivity to a metal nitride layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An etching composition for etching a titanium aluminum nitride layer, the etching composition comprising:
about 15 wt % to about 30 wt % of an oxidizing agent;
about 1 wt % to about 10 wt % of a pH adjusting agent, the pH adjusting agent including an inorganic acid or an organic acid;
about 0.001 wt % to about 1 wt % of an etching booster; and
a solvent, all wt % being based on a total weight of the etching composition.

2. The etching composition as claimed in claim 1, wherein the etching composition has a pH that is greater than 0 and less than or equal to 3.

3. The etching composition as claimed in claim 1, wherein the oxidizing agent includes hydrogen peroxide.

4. The etching composition as claimed in claim 1, wherein the pH adjusting agent includes phosphoric acid, nitric acid, sulfuric acid, hydrochloric acid, acetic acid, methanesulfonic acid, ethanesulfonic acid, benzenesulfonic acid, sulfamic acid, sulfanilic acid, malonic acid, glycolic acid, formic acid, citric acid, oxalic acid, propionic acid, acrylic acid, lactic acid, or butyric acid.

5. The etching composition as claimed in claim 1, wherein the etching booster includes monoammonium phosphate, diammonium phosphate, ammonium triphosphate, ammonium sulfate, ammonium bisulfate, ammonium persulfate, ammonium chloride, ammonium nitrite, ammonium fluoride, methyl methanesulfonate, ethanesulfonate, benzenesulfonate, ammonium sulfamate, ethylenediaminetetraacetic acid, iminodiacetic acid, diethylenetriaminepentaacetic acid, aminotrismethylenephosphonic acid, phosphorous acid, glycine, phenylphosphonic acid, sulfamic acid nitrotrismethylenephosphonic acid, 1-hydroxyethene-1,1-diphosphonic acid, dopamine, or adrenaline.

6. The etching composition as claimed in claim 1, wherein:
the etching composition has a first etching rate for titanium aluminum nitride under a predetermined etching condition, and
the etching composition has a second etching rate for a hafnium oxide, a zirconium oxide, or an aluminum oxide under the predetermined etching condition, the second etching rate being less than the first etching rate.

7. A method of manufacturing an integrated circuit, the method comprising:
forming a semiconductor pattern on a substrate;
forming a gate insulating layer on the semiconductor pattern;
forming a titanium aluminum nitride layer on the gate insulating layer; and
performing an etching process using a composition on the titanium aluminum nitride layer to remove the titanium aluminum nitride layer,
wherein the composition includes the etching composition of claim 1.

8. The method as claimed in claim 7, wherein the gate insulating layer is not removed and remains after the etching process.

9. The method as claimed in claim 8, wherein the gate insulating layer includes a metal oxide, the metal oxide including a hafnium oxide, a zirconium oxide, or an aluminum oxide.

10. The method as claimed in claim 9, wherein:
the composition has a first etching rate for a titanium aluminum nitride under a predetermined etching condition, and
the composition has a second etching rate for the metal oxide under the predetermined etching condition, the second etching rate being less than the first etching rate.

11. The method as claimed in claim 7, wherein:
the composition has a pH that is greater than 0 and less than or equal to 3, and
the oxidizing agent includes hydrogen peroxide.

12. The method as claimed in claim 7, wherein the pH adjusting agent includes phosphoric acid, nitric acid, sulfuric acid, hydrochloric acid, acetic acid, methanesulfonic acid, ethanesulfonic acid, benzenesulfonic acid, sulfamic acid, sulfanilic acid, malonic acid, glycolic acid, formic acid, citric acid, oxalic acid, propionic acid, acrylic acid, lactic acid, or butyric acid.

13. A method of manufacturing an integrated circuit, the method comprising:
forming a first semiconductor pattern structure on a first region of a substrate such that the first semiconductor pattern structure includes a plurality of first semiconductor patterns separated from each other;
forming a second semiconductor pattern structure on a second region of the substrate such that the second semiconductor pattern structure includes a plurality of second semiconductor patterns separated from each other;
forming a gate insulating layer on the first semiconductor pattern structure and the second semiconductor pattern structure;
forming a metal-containing layer on the gate insulating layer such that the metal-containing layer includes a titanium aluminum nitride;
forming a mask pattern that covers a first portion of the metal-containing layer on the first region and does not cover a second portion of the metal-containing layer on the second region; and
performing an etching process using a composition on the second portion of the metal-containing layer to remove the second portion of the metal-containing layer,
wherein the composition includes the etching composition of claim 1.

14. The method as claimed in claim 13, wherein:
the metal-containing layer not covered by the mask pattern is removed at a first etching rate during the etching process,
the gate insulating layer under the metal-containing layer is removed at a second etching rate that is less than the first etching rate during the etching process, and
the mask pattern is removed at a third etching rate that is less than the first etching rate during the etching process.

15. The method as claimed in claim 14, wherein the second etching rate is about 0.1% to about 10% of the first etching rate.

16. The method as claimed in claim 13, wherein the gate insulating layer includes a metal oxide, the metal oxide including a hafnium oxide, a zirconium oxide, or an aluminum oxide.

17. The method as claimed in claim 13, wherein:
the composition has a pH that is greater than 0 and less than or equal to 3, and
the oxidizing agent includes hydrogen peroxide.

18. The method as claimed in claim 13, wherein the pH adjusting agent includes phosphoric acid, nitric acid, sulfuric acid, hydrochloric acid, acetic acid, methanesulfonic acid, ethanesulfonic acid, benzenesulfonic acid, sulfamic acid, sulfanilic acid, malonic acid, glycolic acid, formic acid, citric acid, oxalic acid, propionic acid, acrylic acid, lactic acid, or butyric acid.

19. The method as claimed in claim 13, wherein:
the gate insulating layer surrounds each of the plurality of first semiconductor patterns and each of the plurality of second semiconductor patterns,
the first portion of the metal-containing layer fills first sub-gate spaces between the plurality of first semiconductor patterns, and
the second portion of the metal-containing layer fills second sub-gate spaces between the plurality of second semiconductor patterns.

20. The method as claimed in claim 19, wherein, after the second portion of the metal-containing layer is removed, the gate insulating layer is exposed in the second sub-gate spaces between the plurality of first semiconductor patterns.
